(19) United States
(12) Patent Application Publication
(10) Pub. No.: US 2019/0200472 A1
(43) Pub. Date: Jun. 27, 2019

(54) STACKED STRUCTURE AND METHOD OF MANUFACTURING THE SAME AND WINDOW FOR DISPLAY DEVICE AND DISPLAY DEVICE

(71) Applicant: Samsung Electronics Co., Ltd., Suwon-si (KR)

(72) Inventors: Myong Jong KWON, Suwon-si (KR); Ginam Kim, Seongnam-si (KR); Byung Ha Park, Yongin-si (KR); Sung Hun Hong, Hwaseong-si (KR); Du Seop Yoon, Seongnam-si (KR); Won Cheol Jung, Seoul (KR)

(73) Assignee: Samsung Electronics Co., Ltd., Suwon-si (KR)

(21) Appl. No.: 16/180,420

(22) Filed: Nov. 5, 2018

(30) Foreign Application Priority Data
Dec. 21, 2017 (KR) 10-2017-0177476

(51) Int. Cl. H05K 5/03

(52) U.S. Cl. CPC H05K 5/03; H05K 5/0017

(57) ABSTRACT

Disclosed are a stacked structure includes a substrate and a silsesquioxane cured layer disposed on the substrate. The silsesquioxane cured layer may include a plurality of areas having different refractive indexes in a thickness direction. The plurality of areas may include a first area and a second area. The first area may be disposed on a surface of the substrate and the second area may be disposed on the first area. A refractive index of the second area may be higher than a refractive index of the first area. A display device may include the stacked structure.

### CROSS-REFERENCE TO RELATED APPLICATION

This application claims priority to the benefit of Korean Patent Application No. 10-2017-0177476, filed in the Korean Intellectual Property Office on Dec. 21, 2017, the entire contents of which are incorporated herein by reference.

### BACKGROUND

### 1. Field

A stacked structure, a method of manufacturing the same, a window for a display device, and a display device are disclosed.

### 2. Description of the Related Art

Portable electronic devices such as a smart phone and a tablet PC have been widely used. These portable electronic devices are used outdoors, as well as indoors, and thus need to secure visibility outdoors where sunlight is strong. In addition, these portable electronic devices need to frequently contact a hand or a pen and thus secure mechanical durability.

### SUMMARY

An embodiment provides a stacked structure capable of satisfying visibility and mechanical durability simultaneously.

Another embodiment provides a window for a display device capable of satisfying visibility and mechanical durability simultaneously.

Yet according to another embodiment, a display device includes the window for a display device.

Still according to another embodiment, a method of manufacturing the stacked structure is provided.

According to an embodiment, a stacked structure includes a substrate and a silsesquioxane cured layer on the substrate. The silsesquioxane cured layer includes a plurality of areas having different refractive indexes in a thickness direction, and the plurality of areas includes a first area and a second area. The first area is disposed on the surface of the substrate. The second area is disposed on the first area. A refractive index of the second area is higher than a refractive index of the first area.

In example embodiments, the plurality of refractive indices silsesquioxane cured layer may range from about 1.20 to about 1.50 at a wavelength of 550 nm.

In example embodiments, the first area and the second area of the silsesquioxane cured layer may have a refractive index difference of greater than or equal to about 0.03 at a wavelength of 550 nm.

In example embodiments, the refractive index of the first area of the silsesquioxane cured layer may be about 1.20 to about 1.40 at a wavelength of 550 nm and the refractive index of the second area of the silsesquioxane cured layer may be about 1.30 to about 1.50 at a wavelength of 550 nm.

In example embodiments, the silsesquioxane cured layer may have a porous structure and a pore density of the second area of the silsesquioxane cured layer may be lower than a pore density of the first area of the silsesquioxane cured layer.

In example embodiments, the silsesquioxane cured layer may include a cured product of silsesquioxane having a weight average molecular weight of greater than about 10,000 and less than or equal to about 500,000 and a polydispersity index (PDI) of greater than or equal to about 3.0.

The stacked structure may have a surface hardness of greater than or equal to about 7.0 GPa.

In example embodiments, the stacked structure may have a reflectance of less than or equal to about 6.2%.

In example embodiments, the stacked structure may have light transmittance of greater than or equal to about 93% and haze of less than or equal to about 1.0.

In example embodiments, the stacked structure may further include an auxiliary layer disposed between the substrate and the silsesquioxane cured layer and a refractive index of the auxiliary layer may be higher than a refractive index of the silsesquioxane cured layer.

In example embodiments, a refractive index of the auxiliary layer may be greater than or equal to about 1.7.

According to another embodiment, a window for a display device includes the stacked structure.

According to yet another embodiment, a display device includes the window for a display device.

According to another embodiment, a method of manufacturing a stacked structure includes preparing a coating liquid including a silsesquioxane having a weight average molecular weight of greater than about 10,000 and less than or equal to about 500,000 and about polydispersity index (PDI) of greater than or equal to about 3.0, coating the coating liquid on a substrate, and curing the coating liquid to form a silsesquioxane cured layer including a plurality of areas having different refractive indexes in a thickness direction.

In example embodiments, the silsesquioxane may include hydrogen silsesquioxane.

In example embodiments, the preparing the coating liquid may include adding the silsesquioxane to an organic solvent including water or alcohols, and stirring a mixture including the silsesquioxane and the organic solvent for about 1 hour to about 10 hours to prepare coating liquid including silsesquioxane.

In example embodiments, the silsesquioxane cured layer may include a first area disposed on a surface of the substrate and having a refractive index of about 1.20 to about 1.40 at a wavelength of 550 nm and a second area disposed on the first area and having a refractive index of about 1.30 to about 1.50 at a wavelength of 550 nm.

In example embodiments, the silsesquioxane cured layer may have a porous structure and a pore density of the second area of the silsesquioxane cured layer may be lower than pore density of the first area of the silsesquioxane cured layer.

In example embodiments, the method may further include forming an auxiliary layer before coating the coating liquid. A refractive index of the auxiliary layer may be higher than a refractive index of the silsesquioxane cured layer.

In example embodiments, the forming of the auxiliary layer may include depositing Al₂O₃, TiO₂, ZrO₂, Si₃N₄, or a combination thereof on the substrate.

Outdoor visibility and mechanical durability may be simultaneously satisfied.

### BRIEF DESCRIPTION OF THE DRAWINGS

FIG. 1 is a schematic cross-sectional view of a stacked structure according to an embodiment,

FIG. 2 is a schematic cross-sectional view of a stacked structure according to another embodiment,

FIG. 3 is a cross-sectional view of a display device according to an embodiment,

FIG. 4 is a cross-sectional view of a display device according to another embodiment,

FIG. 5 is a graph showing a molecular weight distribution of the hydrogen silsesquioxane solution according to Preparation Example 3,

FIG. 6 is a graph showing a molecular weight distribution of the hydrogen silsesquioxane solution according to Comparative Example 1,

FIG. 7 is a TEM photograph of the stacked structure according to Example 3,

FIG. 8 is a TEM photograph of the stacked structure according to Comparative Example 1, and

FIGS. 9 to 11 are SEM photographs showing surface images after fingerprint resistance tests of the stacked structures according to Example 3, and Reference Example 1 and 2, respectively.

### DETAILED DESCRIPTION

Example embodiments of the present disclosure will hereinafter be described in detail, and may be easily performed by those who have common knowledge in the related art. However, actually applied structures may be embodied in many different forms, and should not be construed as limited to the example embodiments set forth herein.

In the drawings, the thickness of layers, films, panels, regions, etc., are exaggerated for clarity. Like reference numerals designate like elements throughout the specification. It will be understood that when an element such as a layer, a film, a region, or a substrate is referred to as being “on” another element, it can be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

Hereinafter, ‘combination’ refers to a mixture of two or more and a stack structure of two or more.

Hereinafter, a stacked structure according to an embodiment is described.

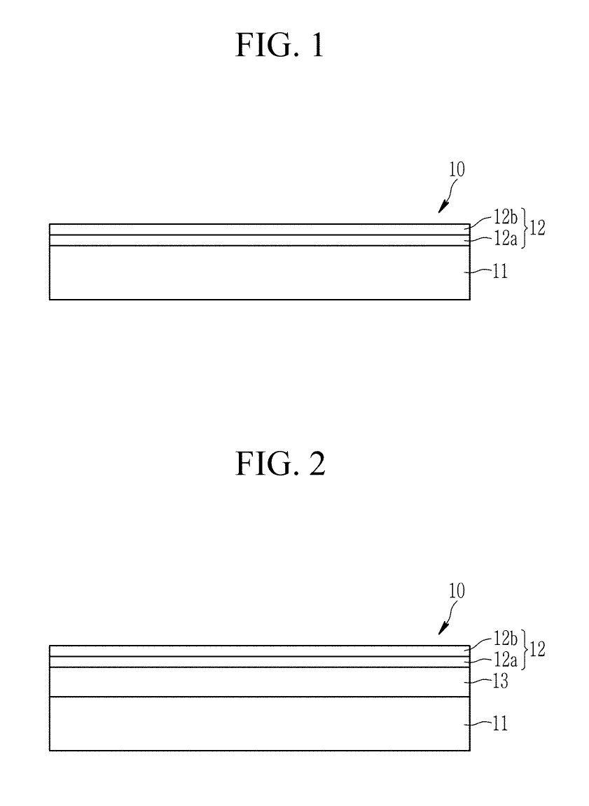

FIG. 1 is a schematic cross-sectional view of a stacked structure according to an embodiment.

Referring to FIG. 1, a stacked structure 10 according to an embodiment includes a substrate 11 and a silsesquioxane cured layer 12 disposed on the substrate 11.

The substrate 11 may be a glass or polymer substrate, and the polymer substrate may include for example polyimide, polyamide, polyamideimide, polyethyleneterephthalate, polyethylenenaphthalene, polymethylmethacrylate, polycarbonate, a copolymer thereof or a combination thereof, but is not limited thereto.

The substrate 11 may be for example glass, for example tempered glass.

The substrate 11 may have for example a light transmittance of greater than or equal to about 92% and a reflectance of less than or equal to about 8%. The substrate 11 may have for example a thickness of less than or equal to about 500 μm, for example about 25 μm to about 500 μm or about 50 μm to about 500 μm.

The silsesquioxane cured layer 12 may include a cured product of silsesquioxane. The silsesquioxane may include for example hydrogen silsesquioxane.

The silsesquioxane cured layer 12 may be a single layer and the single layer may include a plurality of areas having a different refractive index along the thickness direction. For example, the silsesquioxane cured layer 12 may include a first area 12a and a second area 12b along the thickness direction. The first area 12a of the silsesquioxane cured layer 12 may be disposed on the surface of the substrate 11 and the second area 12b of the silsesquioxane cured layer 12 may be disposed on the first area 12a and may have a higher refractive index than the first area 12a. The second area 12b of the silsesquioxane cured layer 12 may be for example at the surface of the silsesquioxane cured layer 12.

In the drawing, the first area 12a and the second area 12b are shown as one example, but the present disclosure is not limited thereto but may include an n^{th} area (n is an integer) such as a third area (not shown), a fourth area (not shown), and the like positioned along a thickness direction between the first area 12a and the second area 12b and having a different refractive index. Herein, the silsesquioxane cured layer 12 may have the lowest refractive index in the first area 12a closest to the substrate 11 but the highest refractive index in the second area 12b to the surface, and the refractive index of the silsesquioxane cured layer 12 may be continuously and/or intermittently changed between the first area 12a and the second area 12b.

The silsesquioxane cured layer 12 may have for example a plurality of refractive indices ranging from about 1.20 to about 1.50 at a wavelength of 550 nm, for example a plurality of refractive indices ranging from about 1.23 to about 1.45 at a wavelength of 550 nm.

For example, the first area 12a and the second area 12b of the silsesquioxane cured layer 12 may have a refractive index difference of greater than or equal to about 0.01, for example greater than or equal to about 0.02, greater than or equal to about 0.03, greater than or equal to about 0.04, or greater than or equal to about 0.05 at a wavelength of 550 nm.

For example, the first area 12a of the silsesquioxane cured layer 12 may have a refractive index of about 1.20 to about 1.40 at a wavelength of 550 nm and the second area 12b of the silsesquioxane cured layer 12 may have a refractive index of about 1.30 to about 1.50 at a wavelength of 550 nm. Within the ranges, the first area 12a of the silsesquioxane cured layer 12 may have for example a refractive index of about 1.23 to about 1.40 at a wavelength of 550 nm and the second area 12b of the silsesquioxane cured layer 12 may have for example a refractive index of about 1.33 to about 1.47 at a wavelength of 550 nm; the first area 12a of the silsesquioxane cured layer 12 may have for example a refractive index of about 1.25 to about 1.38 at a wavelength of 550 nm and the second area 12b of the silsesquioxane cured layer 12 may have for example a refractive index of about 1.35 to about 1.45 at a wavelength of 550 nm; or the first area 12a of the silsesquioxane cured layer 12 may have for example a refractive index of about 1.31 to about 1.37 and the second area 12b of the silsesquioxane cured layer 12 may have for example a refractive index of about 1.36 to about 1.42 at a wavelength of 550 nm.

The silsesquioxane cured layer 12 may have a porous structure and a nano-sized micropore. This micropore may be formed, while a cage structure may be changed to a network structure during thermal curing of silsesquioxane.

The silsesquioxane cured layer 12 may include a plurality of areas having different pore density along a thickness direction, and for example, the second area 12b of the silsesquioxane cured layer 12 may have a lower pore density than that of the first area 12a of the silsesquioxane cured layer 12. The above refractive index difference may be realized depending on this pore density difference, and for example, the first area 12a of the silsesquioxane cured layer 12 has relatively high pore density and thus shows a relatively low refractive index, while the second area 12b of the silsesquioxane cured layer 12 has relatively low pore density and thus shows a relatively high refractive index.

The pore density difference may be for example compared by using a transmission electron microscope (TEM). For example, an area having high pore density may look bright compared with an area having low pore density.

The silsesquioxane cured layer 12 having the aforementioned pore density and refractive index distribution may be formed of silsesquioxane having a relatively high weight average molecular weight and relatively wide molecular weight distribution. The molecular weight distribution may be for example expressed by a polydispersity index (PDI), wherein the polydispersity index (PDI) shows how much widely a molecular weight of a polymer compound is distributed and may be expressed as a ratio of a weight average molecular weight (Mw) and a number average molecular weight (Mn).

For example, the silsesquioxane cured layer 12 may include a cured product of silsesquioxane having a weight average molecular weight of greater than about 10,000 and less than or equal to about 500,000 and a polydispersity index (PDI) of greater than about 3.0.

The silsesquioxane may have for example a weight average molecular weight of greater than about 10,000 and less than or equal to about 300,000, greater than about 10,000 and less than or equal to about 250,000, greater than about 10,000 less than or equal to about 200,000, greater than about 10,000 less than or equal to about 180,000, greater than about 10,000 less than or equal to about 150,000, greater than about 10,000 less than or equal to about 120,000, greater than about 10,000 less than or equal to about 110,000, greater than about 10,000 less than or equal to about 100,000 within the range.

The silsesquioxane may have for example a polydispersity index (PDI) of greater than or equal to about 3.1, greater than or equal to about 3.2, greater than or equal to about 3.3, greater than or equal to about 3.5, greater than or equal to about 3.7, greater than or equal to about 3.8, greater than or equal to about 4.0, greater than or equal to about 4.2, greater than or equal to about 4.5, greater than or equal to about 4.7, or greater than or equal to about 5.0 within the range. The cured product of silsesquioxane may have for example a polydispersity index (PDI) of about 3.0 to about 15.0, about 3.1 to about 15.0, about 3.2 to about 15.0, about 3.3 to about 15.0, about 3.5 to about 15.0, about 3.7 to about 15.0, about 3.8 to about 15.0, about 4.0 to about 15.0, about 4.2 to about 15.0, about 4.5 to about 15.0, about 4.7 to about 15.0, or about 5.0 to about 15.0 within the range.

Silsesquioxane having this high weight average molecular weight and wide molecular weight distribution may form a gradient of pore density in a single layer through one coating and thus be cured to obtain the silsesquioxane cured layer 12 having a pore density and refractive index distribution along a thickness direction as described above.

Accordingly the silsesquioxane cured layer 12 may have high pore density and thus a low refractive index at the first area 12a near to the substrate 11 and thereby may endow the stacked structure 10 with low reflectance or anti-reflection characteristics. For example, the stacked structure 10 may have for example reflectance of less than or equal to about 6.2%, less than or equal to about 6.1%, less than or equal to about 6.0%, less than or equal to about 5.9%, less than or equal to about 5.7%, less than or equal to about 5.5%, less than or equal to about 5.4%, less than or equal to about 5.3%, or less than or equal to about 5.2%.

Meanwhile, the silsesquioxane cured layer 12 has a low pore density at the second area 12b disposed on the surface and thereby may endow improved the surface of the stacked structure 10 with mechanical durability. For example, the surface of the stacked structure 10 may have scratch resistance characteristic, high surface hardness, and pencil hardness. For example, the stacked structure 10 may have a surface hardness of greater than or equal to about 7.0 GPa, greater than or equal to about 7.1 GPa, greater than or equal to about 7.2 GPa, greater than or equal to about 7.3 GPa, or greater than or equal to about 7.4 GPa. For example, the stacked structure 10 may have a surface hardness of about 7.0 GPa to about 15 GPa, about 7.1 GPa to about 15 GPa, about 7.2 GPa to about 15 GPa, about 7.3 GPa to about 15 GPa, or about 7.4 GPa to about 15 GPa. For example, the stacked structure 10 may have a pencil hardness of about 5H or greater, about 6H or greater, about 7H or greater, about 8H or greater, about 9H or greater.

Accordingly, the silsesquioxane cured layer 12 may realize anti-reflection characteristics and hard coating characteristics and/or scratch resistance characteristics simultaneously and thus visibility and mechanical durability may be satisfied simultaneously.

The silsesquioxane cured layer 12 may further include a nanoparticle as needed and the nanoparticle may be for example inorganic nanoparticle, for example silica, alumina, magnesium fluoride (MgF₂) or a combination thereof, but is not limited thereto.

The stacked structure 10 may be a transparent stacked structure and may satisfy, for example light transmittance of greater than or equal to about 93% and haze of less than or equal to about 1.0.

Hereinafter, an example of a method of manufacturing the stacked structure of FIG. 1 is described.

A method of manufacturing the stacked structure according to an embodiment includes preparing coating liquid including silsesquioxane, coating the coating liquid on the substrate, and curing the coating liquid to form a silsesquioxane cured layer including a plurality of areas having a different refractive index in a thickness direction.

The silsesquioxane may include hydrogen silsesquioxane.

The coating liquid may include silsesquioxane having a weight average molecular weight of greater than about 10,000 and less than or equal to about 500,000 and a polydispersity index (PDI) of greater than or equal to about 3.0, for example may be prepared by adding silsesquioxane having a weight average molecular weight of about 3,000 to about 15,000 to an organic solvent and stirring the same.

The solvent is not particularly limited if it dissolves and/or disperses the components and may be for example one or more selected from a ketone-based solvent such as methyl isobutyl ketone (MIBK), 1-methyl-2-pyrrolidinone (NMP), cyclohexanone, acetone, and the like; an aliphatic hydrocarbon solvent such as hexane, heptane, and the like; an aromatic hydrocarbon solvent such as toluene, pyridine, quinoline, anisole, mesitylene, xylene, and the like; an ether-based solvent such as tetrahydrofuran, isopropyl ether, and the like; an acetate based solvent such as ethyl acetate, butyl acetate, propylene glycol methyl ether acetate, and the like; an amide based solvent such as dimethylacetamide, dimethylformamide (DMF), and the like; a nitrile-based solvent such as acetonitrile, benzonitrile, and the like; and a mixture of the foregoing solvents, but is not limited thereto.

Herein, the organic solvent may further include a small amount of water or alcohol, and as the silsesquioxane reacts with water or alcohol, the weight average molecular weight and polydispersity index (PDI) of the silsesquioxane may be increased.

For example, the coating liquid may be, for example, stirred for about 1 hour to about 10 hours, so that silsesquioxane having a weight average molecular weight of about 3,000 to about 15,000 may sufficiently react with water or alcohol. This stirring may sufficiently react silsesquioxane with water or alcohol, and accordingly, the coating liquid may include silsesquioxane having a higher weight average molecular weight and polydispersity index (PDI) than those of the supplied silsesquioxane, for example, a weight average molecular weight of greater than about 10,000 and less than or equal to about 500,000 and a polydispersity index (PDI) of greater than or equal to about 3.0.

The silsesquioxane may be included in an amount of about 0.1 wt % to about 50 wt %, for example about 1 wt % to about 45 wt %, about 3 wt % to about 43 wt %, about 5 wt % to about 40 wt %, about 10 wt % to about 40 wt %, about 15 wt % to about 35 wt %, or about 20 wt % to about 30 wt % in the coating liquid.

The coating liquid may further include various additives, for example, a surface characteristic controller, a reaction initiator, a polymerization accelerator, an ultraviolet (UV) absorber, an antistatic agent, and the like but is not limited thereto.

The coating liquid may be formed into a cured product such as a film through coating, drying, and curing.

The coating liquid may be for example coated with a solution process, for example a spin coating, a slit coating, a bar coating, a dip coating, a spray coating, an inkjet printing, and the like, but is not limited thereto.

The drying may be for example once or more than once performed at about 70° C. to about 150° C.

The curing may be photo curing and/or thermal curing. The photo curing may for example use a xenon lamp, a high pressure mercury lamp, a metal halide lamp, and the like and a light dose or a radiation time may be controlled as needed. The thermal curing may be for example performed at about 200° C. to 400° C., and the number and time of heat treatment may be controlled as needed.

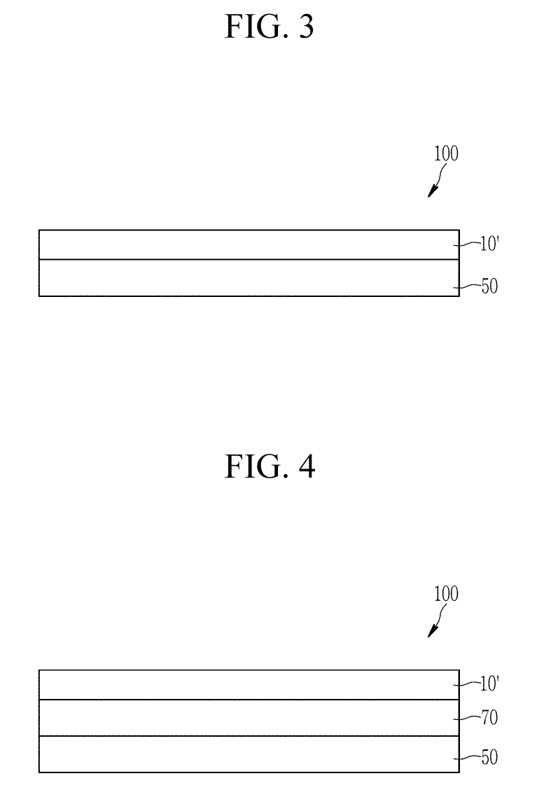

FIG. 2 is a schematic cross-sectional view of a stacked structure according to another embodiment.

Referring to FIG. 2, the stacked structure according to the present embodiment includes a substrate 11 and a silsesquioxane cured layer 12 like the above embodiment. The substrate 11 and the silsesquioxane cured layer 12 are the same as described above.

However, the stacked structure according to the present embodiment further includes an auxiliary layer 13 disposed between the substrate 11 and the silsesquioxane cured layer 12, unlike the stacked structure according to the above embodiment.

The auxiliary layer 13 is a high refractive index layer having higher refractive index than the silsesquioxane cured layer 12 and may have, for example a refractive index of greater than or equal to about 1.7. The auxiliary layer 13 may include for example Si₃N₄, Al₂O₃, TiO₂, ZrO₂ or a combination thereof, but is not limited thereto.

The stacked structure 10 may have further improved anti-reflection characteristics due to the auxiliary layer 13.

Hereinafter, a method of manufacturing the stacked structure of FIG. 2 is described.

A method of manufacturing the stacked structure according to an embodiment includes preparing a coating liquid including silsesquioxane, forming an auxiliary layer on a substrate, coating the coating liquid on the auxiliary layer, and curing the coating liquid to form a silsesquioxane cured layer including a plurality of areas having a different refractive index in a thickness direction.

The auxiliary layer may have for example a higher refractive index than the silsesquioxane cured layer and may be formed by depositing an inorganic material having, for example a refractive index of about 1.7. The forming of the auxiliary layer may include for example depositing Al₂O₃, TiO₂, ZrO₂, Si₃N₄, or a combination thereof and may be, for example formed in a thickness of about 10 nm to 140 nm.

The stacked structure may be applied to a window for a display device.

The window for a display device may realize anti-reflection characteristics and hard coating characteristics and/or scratch resistance characteristics due to the stacked structure simultaneously and thus may ensure visibility and mechanical durability simultaneously.

The window for a display device may further include another auxiliary layer (not shown) on the lower and/or upper surface of the stacked structure.

The window for a display device may be applied to various electronic devices. The electronic devices may be display devices, for example liquid crystal displays (LCD) or organic light emitting diode (OLED) displays, but are not limited thereto.

The window for a display device may be attached on the display panel. Herein, the display panel and the window for a display device may be directly bonded or may be bound by interposing an adhesive or a tackifier.

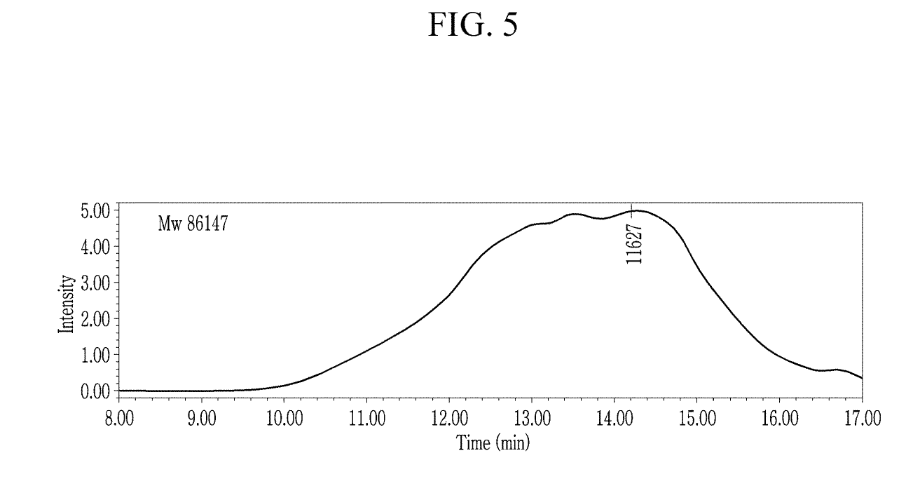

FIG. 3 is a cross-sectional view of a display device according to an embodiment.

Referring to FIG. 3, a display device 100 according to an embodiment includes a display panel 50, a window 10′ for a display device, and an adhesion layer (not shown).

The display panel 50 may be for example an organic light emitting display panel or a liquid crystal display panel.

The window 10′ for a display device may be disposed on the side of an observer, and the structure thereof is the same as the stacked structure 10.

The display panel 50 and the window 10′ for a display device may be bonded by the adhesion layer. The adhesion layer may include a tackifier or an adhesive, for example optical clear adhesive (OCA). The adhesion layer may be omitted.

Another layer may be interposed between the display panel 50 and the window 10′ for a display device. For example, a single layer or plural layers of polymer layer (not shown) and optionally a transparent adhesion layer (not shown) may be further included.

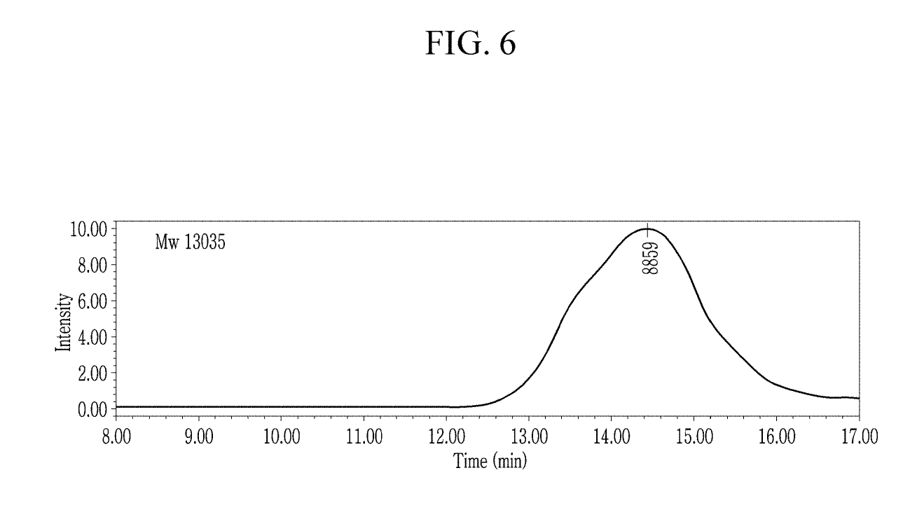

FIG. 4 is a cross-sectional view of a display device according to another embodiment.

Referring to FIG. 4, the display device 200 according to the present embodiment includes a display panel 50, a window 10′ for a display device, and a touch panel 70 disposed between the display panel 50 and the window 10′ for a display device.

The display panel 50 may be for example an organic light emitting display panel or a liquid crystal display panel.

The window 10′ for a display device may be disposed on the side of an observer, and the structure thereof is the same as the stacked structure 10.

The touch panel 70 may be disposed adjacent to each of the window 10′ for a display device and the display panel 50 to recognize the touched position and the position change when is touched by a human hand or a material through the window 10′ for a display device and then to output a touch signal. The driving module (not shown) may monitor a position where is touched from the output touch signal; recognize an icon marked at the touched position; and control to carry out functions corresponding to the recognized icon, and the function performance results are displayed on the display panel 50.

Another layer may be interposed between the touch panel 70 and the window 10′ for a display device. For example, a single layer or plural layers of polymer layer (not shown) and optionally a transparent adhesion layer (not shown) may be further included.

The display device may be applied to a variety of electronic devices such as a smart phone, a tablet PC, a camera, a touch screen device, and so on, but is not limited thereto.

Hereinafter, the embodiments are illustrated in more detail with reference to examples. However, these examples are exemplary, and the present disclosure is not limited thereto.

### PREPARATION EXAMPLES

### Preparation Example 1

25 wt % of hydrogen silsesquioxane (Fox 16, Dow Corning) is dissolved in a methylisobutylketone solvent including 0.3 wt % of water to prepare 3 wt % of a hydrogen silsesquioxane solution. Subsequently, the hydrogen silsesquioxane solution is stirred at room temperature and 300 RPM for 1 hour to prepare a hydrogen silsesquioxane solution having a weight average molecular weight of 20,133 and polydispersity index (PDI) of 3.24.

### Preparation Example 2

The hydrogen silsesquioxane solution is stirred for 2 hours to prepare a hydrogen silsesquioxane solution having a weight average molecular weight of 38,965 and a polydispersity index (PDI) of 5.65.

### Preparation Example 3

The hydrogen silsesquioxane solution is stirred for 3 hours to prepare a hydrogen silsesquioxane solution having a weight average molecular weight of 86,147 and a polydispersity index (PDI) of 9.86.

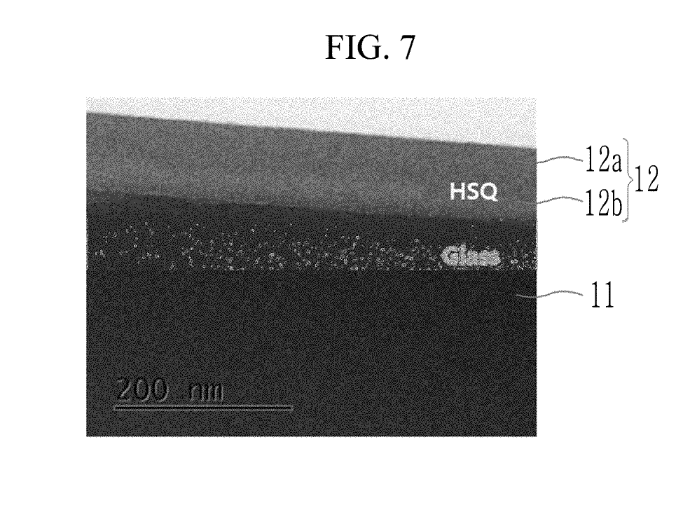

FIG. 5 is a graph showing a molecular weight distribution of the hydrogen silsesquioxane solution according to Preparation Example 3.

### Preparation Example 4

The hydrogen silsesquioxane solution is stirred for 4 hours to prepare a hydrogen silsesquioxane solution having a weight average molecular weight of 192,971 and a polydispersity index (PDI) of 11.19.

### Comparative Preparation Example 1

25 wt % of hydrogen silsesquioxane (Fox 16, Dow Corning) is dissolved in a methylisobutylketone solvent to prepare a hydrogen silsesquioxane solution having a weight average molecular weight of 13,035 and a polydispersity index (PDI) of 2.29.

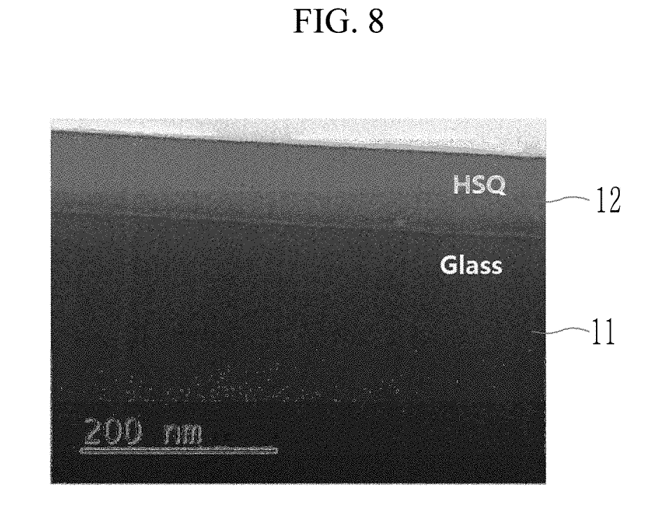

FIG. 6 is a graph showing a molecular weight distribution of the hydrogen silsesquioxane solution according to Comparative Example 1.

### EXAMPLES

### Example 1

The hydrogen silsesquioxane solution of Preparation Example 1 is spin-coated on a tempered glass (Gorilla glass, Corning) at 3,000 rpm to form a thin film, dried on a 150° C. hot plate for 15 minutes, and heat-treated in a 300° C. furnace for 30 minutes to form a 77 nm-thick silsesquioxane cured layer and thus fabricate a stacked structure.

### Example 2

A stacked structure is fabricated by spin-coating the hydrogen silsesquioxane solution according to Preparation Example 2 on a tempered glass at 3,000 rpm to form a thin film and then, drying it on a 150° C. hot plate for 15 minutes and heat-treating it in a 300° C. furnace for 30 minutes to form a 85 nm-thick silsesquioxane cured layer.

### Example 3

A stacked structure is fabricated by spin-coating the hydrogen silsesquioxane solution according to Preparation Example 3 on a tempered glass at 3,000 rpm to form a thin film and then, drying it on a 150° C. hot plate for 15 minutes and heat-treating it in a 300° C. furnace for 30 minutes to form a 88 nm-thick silsesquioxane cured layer.

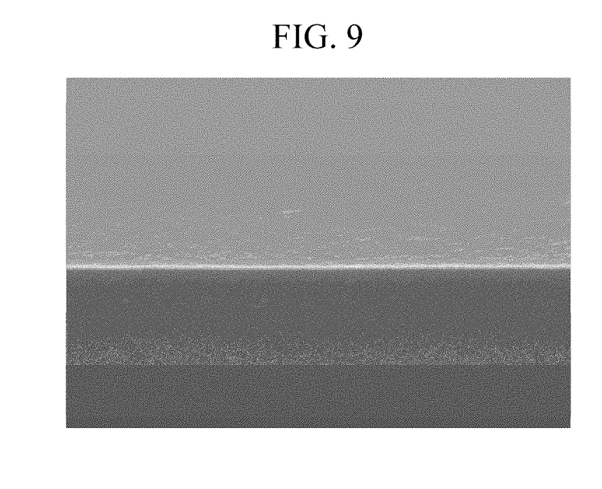

FIG. 7 is a TEM photograph of the stacked structure according to Example 3.

In TEM photograph of FIG. 7, a first area 12a having high pore density looks brighter than a second area 12b having low pore density.

### Example 4

A stacked structure is fabricated by spin-coating the hydrogen silsesquioxane solution according to Preparation Example 4 on a tempered glass at 3,000 rpm to form a thin film and then, drying it on a 150° C. hot plate for 15 minutes and heat-treating it in a 300° C. furnace for 30 minutes to form a 107 nm-thick silsesquioxane cured layer.

### Comparative Example 1

A stacked structure is fabricated by spin-coating the hydrogen silsesquioxane solution according to Comparative Preparation Example 1 on a tempered glass at 3,000 rpm to form a thin film and then, drying it on a 150° C. hot plate for 15 minutes and heat-treating it in a 300° C. furnace for 30 minutes to form a silsesquioxane cured layer.

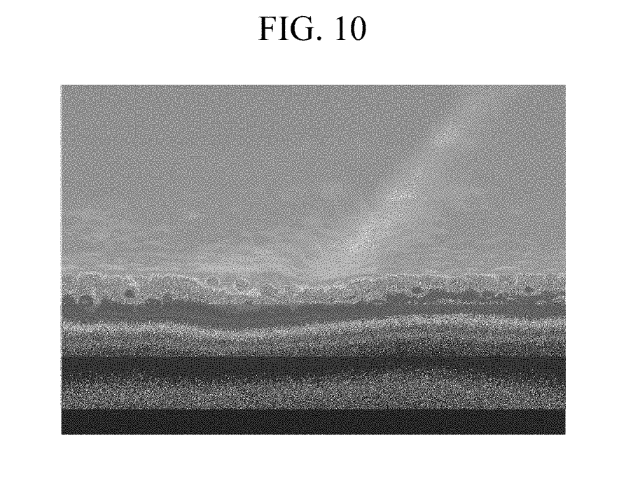

FIG. 8 is a TEM photograph showing the stacked structure according to Comparative Example 1.

### Reference Example 1

A stacked structure including hollow silica is prepared in a method disclosed in U.S. Pat. No. 9,417,361.

### Reference Example 2

A stacked structure in a porous nanostructure is prepared in a method disclosed in U.S. Pat. No. 8,741,158.

### EVALUATION

A refractive index and reflectance of the stacked structures according to Examples 1 to 4 and Comparative Example 1 are evaluated.

The refractive index is measured within a wavelength range of about 380 nm to 760 nm by using Ellipsometer (J.A.Woollam Co., Inc.).

The reflectance is measured by using a UV spectrophotometer (cm-3600d, Konica Minolta Inc.).

The results are shown in Table 1.

TABLE 1

| | Silsesquioxane molecular | | Refractive index | | |
|---|---|---|---|---|---|
| | weight (Dalton) | | (@550 nm) | | Reflectance |
| | Mw | PDI | Top | Bottom | (%) |
| Example 1 | 20,133 | 3.24 | 1.42 | 1.37 | 5.9 |
| Example 2 | 38,965 | 5.65 | 1.41 | 1.34 | 5.5 |
| Example 3 | 86,147 | 9.86 | 1.39 | 1.33 | 5.2 |
| Example 4 | 192,971 | 11.19 | 1.36 | 1.31 | 4.9 |

| | | | | |
|---|---|---|---|---|
| Comparative | 13,035 | 2.29 | 1.41 | 6.3 |
| Example 1 | | | | |

Referring to Table 1, the stacked structures according to Examples 1 to 4 has lower reflectance than that of the stacked structure according to Comparative Example 1.

### Evaluation 2

Mechanical durability of the stacked structures according to Example 3 and Reference Examples 1 and 2 is evaluated.

The mechanical durability is evaluated by measuring surface hardness, pencil hardness, finger print resistance characteristics, and scratch resistance characteristics.

The surface hardness is measured by using a nanoindenter (Helmut Fisher, Fischerscope HM2000) under a load of 10 mN for 20 seconds.

The pencil hardness is measured by using a pencil hardness meter and a Mitsubishi pencil according to ASTM D3363.

The finger print resistance characteristics is evaluated by respectively coating an anti-fingerprint (AF) (UD-509, Japan Daikin Industries Ltd.) on the surface of the stacked structures and measuring an initial water contact angle thereon. Subsequently, a contact angle is measured again after 3000 times moving back and forth an eraser having a diameter of 6 mm and a load of 1 kg by using an eraser abrasion resistance tester. A contact angle difference before and after the finger print resistance evaluation is a delta contact angle, and when the delta contact angle is less than 20° after the 3000 times test with the load of 1 kg load, “good” is given, and when the delta contact angle is greater than or equal to 20° after the 3000 times test with the load of 1 kg load, “inferior” is given.

The scratch resistance characteristics are evaluated by coating an anti-fingerprint (AF) (UD-509, Japan Daikin Industries Ltd.) on the surface of the stacked structures by using a scuff test (COAD.108, Ocean Science).

Specifically, the scratch resistance characteristics is evaluated by respectively fixing the stacked structures according to Example 3 and Comparative Example 1 on a glass plate and then, putting a Φ20 cylinder wound with steel wool #0000 on the films. After putting a weight of 1.5 Kg on a pendulum connected to the cylinder, the pendulum connected to the cylinder is 10 times moved back and forth at 45 times/min. Then, whether or not a scratch is generated on the surface of the stacked structures are examined with naked eyes.

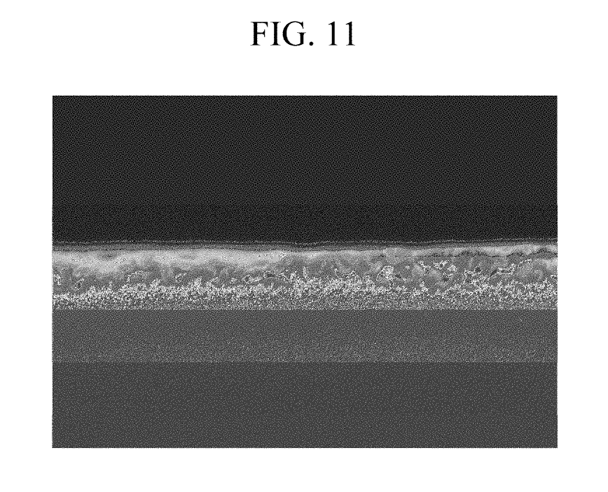

The results are shown in Table 2 and FIGS. 9 to 11.

FIGS. 9 to 11 are SEM photographs showing surface images after fingerprint resistance tests of the stacked structures according to Example 3 and Reference Example 1 and 2, respectively.

TABLE 2

| | | Reference | Reference |
|---|---|---|---|
| | Example 3 | Example 1 | Example 2 |
| Surface hardness (GPa) | 7.3 | 5.9 | 4.5 |
| Pencil hardness | >9H | <1H | <<1H |
| Fingerprint resistance | Good | Good | Inferior |
| Scratch resistance | Good | Inferior | Inferior |

Referring to Table 2 and FIGS. 9 to 11, the stacked structure according to Example 3 has high surface hardness and pencil hardness and improved fingerprint resistance and scratch resistance compared with the stacked structures according to Reference Examples 1 and 2.

### Evaluation 3

Light transmittance and haze of the stacked structures according to Examples 1 to 4 are evaluated.

The light transmittance and the haze are measured by using a UV spectrophotometer (cm-3600d, Konica Minolta Inc.). The light transmittance is, for example, transmittance over the entire visible ray region of about 380 nm to 700 nm, and the haze is measured by using D1003-97(A).

The results are shown in Table 3.

TABLE 3

| | Light transmittance (%) | Haze |
|---|---|---|
| Example 1 | 94.08 | 0.14 |
| Example 2 | 94.42 | 0.13 |
| Example 3 | 94.76 | 0.12 |
| Example 4 | 94.91 | 0.12 |
| Comparative | 93.92 | 0.18 |
| Example 1 | | |

The stacked structures according to Examples 1 to 4 are equivalent or improved light transmittance and haze compared with the stacked structure according to Comparative Example 1.

While this disclosure has been described in connection with what is presently considered to be practical example embodiments, it is to be understood that inventive concepts described herein are not limited to the disclosed embodiments, but, on the contrary, are intended to cover various modifications and equivalent arrangements included within the spirit and scope of the appended claims.

What is claimed is:

1. A stacked structure comprising:
a substrate; and
a silsesquioxane cured layer disposed on the substrate,
the silsesquioxane cured layer includes a plurality of areas having different refractive indexes in a thickness direction,
the plurality of areas including a first area and a second area,
the first area disposed on a surface of the substrate,
the second area disposed on the first area, and
a refractive index of the second area being higher than a refractive index of the first area.

2. The stacked structure of claim 1, wherein the plurality of refractive indexes in the silsesquioxane cured layer range from about 1.20 to about 1.50 at a wavelength of 550 nm.

3. The stacked structure of claim 1, wherein the first area and the second area of the silsesquioxane cured layer have a refractive index difference of greater than or equal to about 0.03 at a wavelength of 550 nm.

4. The stacked structure of claim 1, wherein
the refractive index of the first area of the silsesquioxane cured layer is about 1.20 to about 1.40 at a wavelength of 550 nm, and
the refractive index of the second area of the silsesquioxane cured layer is about 1.30 to about 1.50 at a wavelength of 550 nm.

5. The stacked structure of claim 1, wherein
the silsesquioxane cured layer has a porous structure, and
a pore density of the second area of the silsesquioxane cured layer is lower than a pore density of the first area of the silsesquioxane cured layer.

6. The stacked structure of claim 1, wherein
the silsesquioxane cured layer includes a cured product of silsesquioxane having a weight average molecular weight of greater than about 10,000 and less than or equal to about 500,000 and a polydispersity index (PDI) of greater than or equal to about 3.0.

7. The stacked structure of claim 1, wherein the stacked structure has a surface hardness of greater than or equal to about 7.0 GPa.

8. The stacked structure of claim 1, wherein the stacked structure has a reflectance of less than or equal to about 6.2%.

9. The stacked structure of claim 1, wherein the stacked structure has light transmittance of greater than or equal to about 93% and a haze of less than or equal to about 1.0.

10. The stacked structure of claim 1, further comprising:
an auxiliary layer disposed between the substrate and the silsesquioxane cured layer, wherein
a refractive index of the auxiliary layer is higher than a refractive index than the silsesquioxane cured layer.

11. The stacked structure of claim 10, wherein the refractive index of the auxiliary layer is greater than or equal to about 1.7.

12. A window for a display device comprising:
the stacked structure of claim 1.

13. A display device comprising:
the window for a display device of claim 12.

14. A method of manufacturing a stacked structure, comprising
preparing a coating liquid including a silsesquioxane having a weight average molecular weight of greater than about 10,000 and less than or equal to about 500,000 and about polydispersity index (PDI) of greater than or equal to about 3.0,
coating the coating liquid on a substrate, and
curing the coating liquid to form a silsesquioxane cured layer including a plurality of areas having different refractive indexes in a thickness direction.

15. The method of claim 14, wherein the silsesquioxane includes hydrogen silsesquioxane.

16. The method of claim 14, wherein
the preparing the coating liquid includes adding the silsesquioxane to an organic solvent including water or alcohols, and stirring a mixture including the silsesquioxane and the organic solvent for about 1 hour to about 10 hours to prepare the coating liquid including the silsesquioxane.

17. The method of claim 14, wherein the silsesquioxane cured layer includes
a first area disposed on a surface of the substrate, the first area having a refractive index of about 1.20 to about 1.40 at a wavelength of 550 nm, and
a second area disposed on the first area, the second area having a refractive index of about 1.30 to about 1.50 at a wavelength of 550 nm.

18. The method of claim 14, wherein
the silsesquioxane cured layer has a porous structure, and
a pore density of a second area of the silsesquioxane cured layer is lower than a pore density of a first area of the silsesquioxane cured layer.

19. The method of claim 14, further comprising:
forming an auxiliary layer on the substrate before coating the coating liquid, wherein
a refractive index of the auxiliary layer is a higher than a refractive index of the silsesquioxane cured layer.

20. The method of claim 19, wherein the forming the auxiliary layer includes depositing Al₂O₃, TiO₂, ZrO₂, Si₃N₄, or a combination thereof on the substrate.
